(19) United States
(12) Patent Application Publication
(10) Pub. No.: US 2015/0267052 A1
(43) Pub. Date: Sep. 24, 2015

(54) POLYCYCLIC POLYSILOXANE COMPOSITION AND LED CONTAINING SAME

(71) Applicant: OSRAM SYLVANIA INC., Danvers, MA (US)

(72) Inventors: Maxim Tchoul, Beverly, MA (US); Maria Anc, Groveland, MA (US); David Johnston, Kensington, NH (US)

(73) Assignee: OSRAM SYLVANIA INC., Danvers, MA (US)

(21) Appl. No.: 14/430,981

(22) PCT Filed: Sep. 27, 2013
(86) PCT No.: PCT/US13/62490

§ 371 Date: Mar. 25, 2015

Related U.S. Application Data
(60) Provisional application No. 61/706,987, filed on Sep. 28, 2012.

(51) Int. Cl. C08L 83/04; H01L 33/56; H01L 33/50; H01L 33/58

(52) U.S. Cl. CPC C08L 83/04; H01L 33/58; H01L 33/56; H01L 33/502; H01L 33/507; C08L 2203/206

(57) ABSTRACT

The present disclosure describes the use of a polycyclic polysiloxane polymer for light emitting diodes (LEDs). The polymer is characterized by high flame retardancy, high temperature stability, and low moisture and gas permeability. The polymer is useful as a potting compound for encapsulation of phosphors in LED packages, or as a molding resin for producing optical parts for LED light engines, or as a protective coating applied over the light emitting elements.

### CROSS-REFERENCE TO RELATED APPLICATION

The present application claims priority of U.S. Patent Application No. 61/706,987, filed Sep. 28, 2012 and entitled “POLYCYCLIC POLYSILOXANE COMPOSITION AND LED CONTAINING SAME”, the entire contents of which are hereby incorporated by reference.

### BACKGROUND OF THE INVENTION

Polysiloxane elastomers (silicones) have been used in light emitting diodes (LEDs) as an encapsulating matrix for fluorescent phosphors and as a molding resin for lenses and other optical parts. This class of materials exhibits high thermal and light stability, as well as high optical transparency, which make silicones the first material of choice in high power LEDs. At the same time, this class of polymers possesses a number of shortcomings, such as insufficient flame retardancy and relatively high gas and moisture permeability. In addition, the constantly increasing power of LEDs means higher operating temperatures and a demand for more thermally stable encapsulating materials.

Typical commercial optical grade silicones have a UL-94 flammability rating of HB. However, for many LED lighting products, especially those with the exposed optical parts, greater flame retardancy is required. According to the UL-8750 standard “LED Equipment for Use in Lighting Products,” all polymeric materials used as enclosures of non-LVLE and non-Class 2 circuits must have a flammability rating of 5 VA, with the exception of the optical elements (lenses) for which a V-1 rating is allowed. Most of the V-1 and V-0 rated silicones on the market are non-transparent composites filled with non-flammable additives such as talc and mica. There are only few optically transparent products with a V-1 rating and none have a 5 VA rating. At present, only special grades of polycarbonate have a 5 VA rating. However, these materials contain additives that are detrimental to their stability with respect to discoloration. In addition, the process of incorporation of phosphors into a polycarbonate matrix is not as simple and flexible as it is for silicones.

Unlike many polymers, thermal decomposition in polysiloxanes occurs by heterolytic, rather than homolytic chain scission. In the beginning, oxidation of the end groups of the chains results in the formation of silanol groups, Si—OH. Silanol, being relatively acidic, attacks the Si—O— bonds of the main chain. This process results in a mixture of cyclic siloxanes, the most abundant of which are tricyclosiloxanes (D₃) and tetracyclosiloxanes (D₄). These small molecules are volatile and provide the necessary fuel for the flame during the burning of silicones. A logical solution for increasing the thermal stability of silicones would be to alter the chain structure in order to disrupt the intra-molecular scission mechanism. This approach was proposed by Michalczyk et al., “High Temperature Stabilization of Cross-Linked Siloxanes Glasses” Chem. Mater., 5, (1993) 1687-1689. The chemistry involves cyclotetrasiloxane monomers containing vinyl and hydride groups. These groups undergo a hydrosilation reaction, resulting in the formation of a 3-dimentional structure of interconnected rings, where the absence of linear fragments makes the usual chain scission mechanism impossible. The obtained material was reported to have exceptional thermal stability by surviving at 300° C. in air for 1 hour and beginning to decompose only above 500° C.

A number of others have described polymeric compositions that incorporate cyclic siloxanes to some degree. For example, U.S. Pat. Nos. 7,799,887 and 5,124,423 and U.S. Patent Publication No. 2010/0267919 describe thermosetting compositions that are produced by the reaction of cyclic siloxanes with hydrocarbon monomers, such as divinylbenzene, alkene-containing aromatic compounds, and cyclic polyenes respectively. However, these compositions include hydrocarbon moieties to a great extent. It is known that polysiloxanes have greater thermal and light stability than hydrocarbon polymers. Therefore, the minimized presence of hydrocarbon moieties is important to retain these properties. Similarly, U.S. Patent Publication No. 2007/0205399 describes thermosetting compositions produced by reaction of monomers having cyclotetrasiloxane in their structure. As in the previous examples, the monomers contain a large fraction of hydrocarbon moieties, and some of the curing chemistry is based on epoxy condensation, which produces products with lesser thermal and light stability compared to polysiloxanes cured via hydrosilation chemistry. U.S. Patent Publication No. 2010/0225010 describes a polysiloxane composition that incorporates cyclotetrasiloxane in a minor fraction, as a cross-linked agent. However, the main fraction in this composition contains linear polysiloxanes which are susceptible to the heterolytic chain scission reaction as mentioned above. Also, U.S. Pat. No. 7,569,652 and U.S. Patent Publication No. 2006/0041098 describe the preparation of “cyclolinear siloxanes,” polymers with small siloxane rings in the main chains, but does not elaborate on their useful properties or potential applications.

### SUMMARY OF THE INVENTION

The application of the polycyclic polysiloxanes for LED devices is disclosed. The potential benefits are higher thermal stability compared to current silicones and greater flame retardancy, which enables the use of these materials for the devices where these properties are required. Additionally, a high cross-linking density reduces the gas and moisture permeability, making such material useful as a protective coating for LEDs. Penetration of moisture and gases such as oxygen, CO₂, and H₂S through the resin layer in LED packages degrades phosphors and underlying metal parts of the encapsulated elements, resulting in a reduction in efficiency with time and premature failure of the LED. Typically, phenyl-based silicones exhibit lower moisture permeability (ca. 15 g·mm/m²/day) compared to methyl silicones (ca. 50 g·mm/m²/day). However, the presence of phenyl functional groups makes phenyl silicones more susceptible to discoloration. Therefore, novel materials combining high thermal stability with low gas permeability will be beneficial for encapsulation of fluorescent phosphors and LED modules.

In accordance with one embodiment of the invention, there is provided an LED light source, comprising: an LED die and a polymer consisting of a polycyclic polysiloxane polymer, the polycyclic polysiloxane polymer having the general structure:

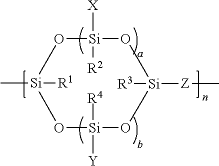

wherein:

(i) Si and O are atoms of silicon and oxygen, respectively, and the structure between the brackets is a repeating unit of the polymer, where n is an integer from 10 to 1000000, and a+b is an integer from 1 to 4;

(ii) R¹, R², R³ and R⁴ are functional groups selected from the group consisting of:
(a) any saturated aliphatic hydrocarbon group of the general formula of CₙH₍₂ₙ₊₁₎, where n is an integer from 1 to 20;
(b) any unsaturated aliphatic hydrocarbon group of the general formula of CₙH₍₂ₙ₋₁₎, where n is an integer from 1 to 20;
(c) any cyclic hydrocarbon group wherein the number of carbon atoms in the cycle is from 4 to 10;
(d) any aromatic hydrocarbon group of the general formula of C₍₆₊ₙ₎H₍₅₊₂ₙ₎ where n is an integer from 0 to 10; and
(e) any fluorocarbon group of the general formula C₂H₄CₙF₍₂ₙ₊₁₎ where n is an integer from 1 to 20;

(iii) Z is selected from the group consisting of:
(a) an oxygen atom;
(b) a siloxane group of the general formula —O—(SiR₂O)ₘ, where R is a functional group of the same type as any one of R¹, R², R³ and R⁴, and m is an integer from 1 to 3; and
(c) a hydrocarbon group of the general formula of (CH₂)ₘ, where m is an integer from 1 to 20;

and, (iv) X and Y are selected from the group consisting of the R¹, R², R³ and R⁴ functional groups and cross-linking sites that connect to cyclosiloxane rings in other polymeric chains to form a 3-dimensional cross-linked structure.

In accordance with another embodiment of the invention, there is provided an LED light source, comprising: an LED die and a polymer consisting of a polycyclic polysiloxane polymer, the polycyclic polysiloxane polymer having the general structure:

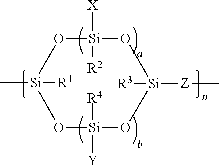

wherein:

(i) Si and O are atoms of silicon and oxygen, respectively, and the structure between the brackets is the repeating unit of the polymer, where n is an integer from 10 to 1000000, and a+b is an integer from 1 to 4;

(ii) R¹, R², R³ and R⁴ are functional groups selected from the group consisting of:
(a) any saturated aliphatic hydrocarbon group of the general formula of CₙH₍₂ₙ₊₁₎, where n is an integer from 1 to 3;
(b) any unsaturated aliphatic hydrocarbon group of the general formula of CₙH₍₂ₙ₋₁₎, where n is an integer from 3 to 5;
(c) any cyclic hydrocarbon group wherein the number of carbon atoms in the cycle is from 4 to 10;
(d) any aromatic hydrocarbon group of the general formula of C₍₆₊ₙ₎H₍₅₊₂ₙ₎ where n is an integer from 0 to 4; and
(e) any fluorocarbon group of the general formula C₂H₄CₙF₍₂ₙ₊₁₎ where n is an integer from 1 to 3;

(iii) Z is selected from the group consisting of:
(a) an oxygen atom;
(b) a siloxane group of the general formula —O—(SiR₂O)ₘ, where R is a functional group of the same type as any one of R¹, R², R³ and R⁴, and m is an integer ranging from 1 to 3; and
(c) a hydrocarbon group of the general formula of (CH₂)ₘ, where m is an integer ranging from 1 to 2;

and, (iv) X and Y are selected from the group consisting of the R¹, R², R³ and R⁴ functional groups and cross-linking sites that connect to cyclosiloxane rings in other polymeric chains to form a 3-dimensional cross-linked structure.

In one preferred embodiment, the functional groups R¹, R², R³ and R⁴ are selected from the group consisting of CH₃, C₃H₅ and C₂H₄CF₃.

In another preferred embodiment, Z is an oxygen atom.

In yet another preferred embodiment, a silicon oxide filler has been dispersed in the polymer and, more preferably, the silicon oxide filler comprises up to 70 percent by weight of the combined weight of the filler and polymer.

### BRIEF DESCRIPTION OF THE DRAWINGS

FIG. 1 is a graphical representation of the optical transmittance of samples prepared in Examples 1 and 2.

FIG. 2 is a graphical representation of the optical transmittance of the 0.6 mm sample of Example 1 after casting (straight line) and after treatment with 1.4 kW/m² blue light at 130° C. for 180 hours (dashed line).

FIG. 3 compares the thermograms in air of commercial HB silicone (thick solid line), and the materials of Example 1 (thin solid line) and Example 2 (dashed line).

FIG. 4 is a graphical representation of the results of a UL-94 vertical flame test for the 2 mm samples of the material of Example 1.

FIG. 5 is a comparison of the emission spectra of polycyclic polysiloxane and commerical methyl silicone polymers containing 3.5 wt. % of a YAG:Ce phosphor.

FIG. 6 is a plot of the loss of water through a polycyclic polysiloxane polymeric membrane (Example 1) as a function of time.

FIG. 7 shows photographs of silver-coated glass slides protected by a silicone gel (left slides) and by a polycyclic polysiloxane polymer (right slides) before (top image) and after 24 hours in a chamber filled with H₂S (bottom image).

FIG. 8 is an illustration of an embodiment of an LED in accordance with this invention.

### DETAILED DESCRIPTION OF THE INVENTION

For a better understanding of the present invention, together with other and further objects, advantages and capabilities thereof, reference is made to the following disclosure and appended claims taken in conjunction with the above-described drawings.

References to the color of a phosphor, LED or conversion material refer generally to its emission color unless otherwise specified. Thus, a blue LED emits a blue light, a yellow phosphor emits a yellow light and so on.

An LED “die” (also referred to as an LED “chip”) is an LED in its most basic form, i.e., in the form of the small individual pieces produced by dicing the much larger wafer onto which the semiconducting layers were deposited. The LED die can include contacts suitable for the application of electric power. An LED package (also referred to as a module) includes the LED die mounted onto a substrate and in the case of a phosphor-conversion (pc)-LED a phosphor conversion element. The LED package may also include other conventional elements such as a silicone encapsulant, optically active components (lenses, reflective sides), a lead frame, and heat dissipating elements. The terms LED package, LED module, LED die etc. may be generally referred to herein by the broader term LED or pc-LED.

In one embodiment, the present disclosure describes an LED device having a blue LED chip encapsulated in a potting material comprising 0-50 weight percent (wt. %) of a phosphor and 50-100% of a polycyclic polysiloxane polymer with the following general structure (Scheme 1):

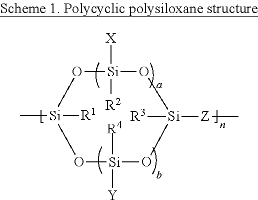

In this generalized structure:
(i) Si and O are atoms of silicon and oxygen correspondingly, the structure between the brackets is the repeating unit of the polymer, where n is the degree of polymerization ranging from 10 to 1000000, and a and b are integers, wherein a+b ranges from 1 to 4;
(ii) the functional groups R¹, R², R³, R⁴, which may be the same or different, are selected from:
   (a) any saturated aliphatic hydrocarbon group of the general formula of CₙH₍₂ₙ₊₁₎, where n is from 1 to 20, more preferably 1 to 3, and most preferably 1;
   (b) any unsaturated aliphatic hydrocarbon group of the general formula of CₙH₍₂ₙ₋₁₎, where n is from 1 to 20, more preferably from 3 to 5, and most preferably 3;
   (c) any cyclic hydrocarbon group with the number of carbon atoms in the cycle is from 4 to 10;
   (d) any aromatic hydrocarbon group of the general formula of C₍₆₊ₙ₎H₍₅₊₂ₙ₎ where n is from 0 to 10, and more preferably from 0 to 4; or
   (e) any fluorocarbon group of the general formula C₂H₄CₙF₍₂ₙ₊₁₎ where n is from 1 to 20, more preferably 1 to 3, and most preferably 1;
(iii) Z is one of the following:
   (a) an oxygen atom;
   (b) a siloxane group of the general formula —O—(SiR₂O), where R is a functional group of the same type as one of R¹, R², R³, and R⁴, and m is an integer ranging from 1 to 3;
   (c) a hydrocarbon group of the general formula of (CH₂), where m is an integer ranging from 1 to 20, and more preferably from 1 to 2;
   and, (iv) X and Y represent either functional groups according to one of R¹, R², R³, and R⁴, or cross-linking sites, i.e. the groups chemically connecting the present cyclosiloxane ring with the corresponding rings of other polymeric chains, to form a 3-dimensional cross-linked structure.

In another embodiment, the present disclosure describes an LED device having an LED package comprising an LED chip and a potting material and a lens made of the composition containing 30-100 wt. % of the polycyclic polysiloxane polymer described in the previous embodiment and 0-70 wt. % of the inorganic filler, such as silicon oxide.

### Example 1

### Sample Preparation

In this example, 6.1 mL of 1,3,5,7-tetravinyl-1,3,5,7-tetramethylcyclotetrasiloxane (herein referred to as D⁴_{V}) was mixed with 4.3 mL of 1,3,5,7-tetramethylcyclotetrasiloxane (herein referred to as D⁴_{H}), and 0.2 mL of a 50 mg/mL solution of a platinum divinyltetramethyldisiloxane complex (herein referred to as the Pt catalyst) in tetrahydrofuran (THF) was added. The mixture was pre-cured by heating at 60° C. for 30 minutes in a closed glass vial. The resulting viscous liquid was poured on a glass slide and into a metal mold, followed by curing in nitrogen at 60° C. for 18 hours and further annealing in nitrogen at 100° C. for 3 hours. The liquid on the glass slide turned into a clear coating with the thickness of 0.4 mm, while the sample in the metal mold cured into a rigid film with the thickness of 0.6 mm.

Characterization.

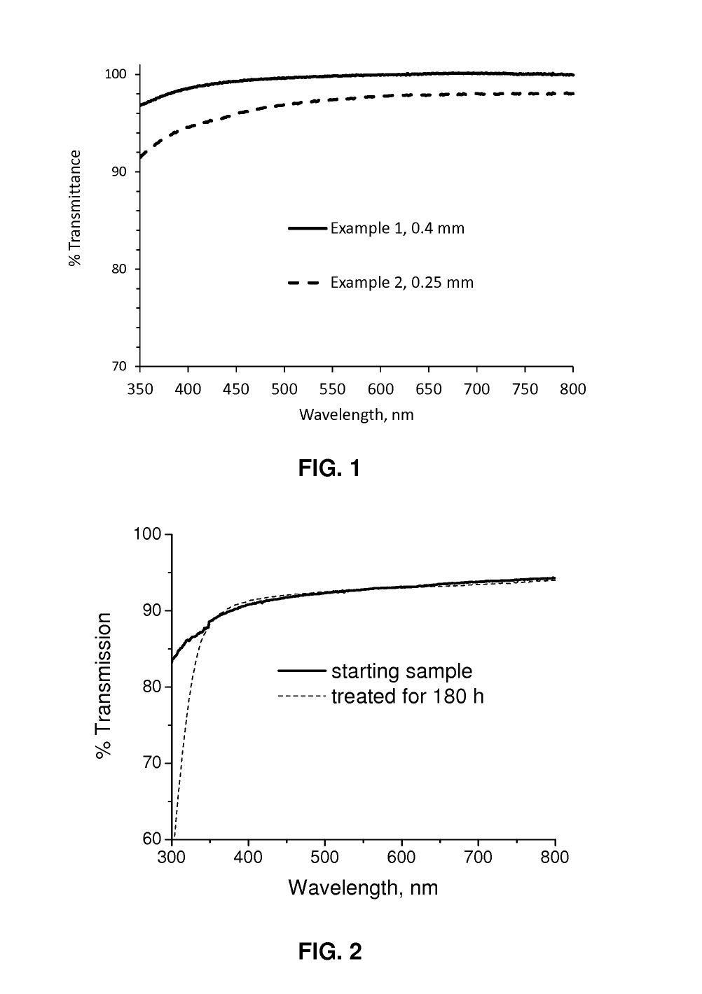

UV-Vis spectroscopy of the film on the glass slide was performed on a CARY-5 UV-Vis-NIR spectrophotometer (Varian, Inc.) with a bare glass slide of the identical thickness used as a background. FIG. 1 presents the UV-Vis transmission spectrum of the 0.4 mm film on glass slide and demonstrates high optical transmittance of the material in the visible range of the spectrum (360-750 nm).

A combined temperature and light stability experiment was performed on a 0.6 mm cast piece of the material in order to predict its stability in LED packages under a high blue-light flux. The sample was placed on a hot plate at a temperature of 130° C., and a blue LED light engine (440 nm) with an optical power of 1.4 kW/m² was positioned at the distance of 2 cm from the sample. The UV-Vis transmission spectrum (FIG. 2) was acquired before and after 180 hours of treatment. No changes in the spectrum within the visible range of the spectrum were observed, indicating a good stability of the material to the combination of heat and blue light.

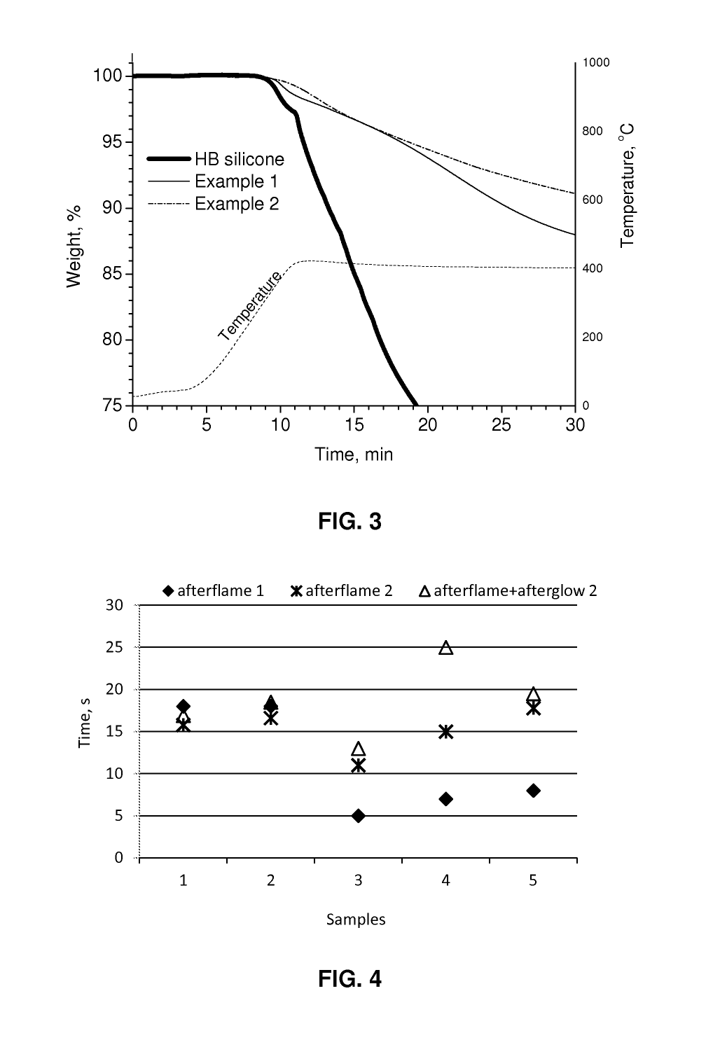

Thermal stability of the material was tested by heating a 30 mg sample in a thermal gravimetric analyzer in air from room temperature to 400° C. at 50° C./min followed by keeping it at this temperature for 60 minutes. The weight loss curves are presented in FIG. 3, where the results for the polycyclic polysiloxane polymer are compared to a typical industrial silicone with a flammability rating of HB (by U-94). The polycyclic polysiloxane polymer has a significantly lower rate of weight loss, indicative of a greater thermal stability.

Flammability experiments were performed according to the requirements of ANSI/UL-94 for vertical flame test. Samples of the material were prepared with the dimensions of 12.5×60×2.0 mm. The samples were subjected to two applications of a 50 W gas burner flame (gas flow rate: 105 mL/min, back pressure: 10 mm water, flame height: 20 mm) for 10 s each. The second application of the burner was done immediately after the flame started by the first application ceased. The first and second afterflame time as well as the combined afterflame and afterglow time after the second application were recorded. The results for a series of 5 samples are presented in FIG. 4. Both the first and second afterflame time for all the samples was less than 30 seconds, and the second combined afterflame and afterglow time did not exceed 60 seconds, all in accordance with a UL-94 V-1 rating.

### Example 2

### Sample Preparation

In this example, 6 mL of D⁴_{V} and 6 mL of D⁴_{H} were measured in separate vials. To each vial, 2 g of hexamethyldisilazane-treated amorphous silica was added and the mixtures were homogenized in a centrifugal planetary mixer. An amount of 5.7 g of the silica-D⁴_{H} mixture was added to the entire amount of silica-D⁴_{V} mixture. The compound was homogenized by stirring with a magnetic stir bar for 12 hours, followed by treatment in an ultrasonic bath for 30 minutes, resulting in a viscous opaque suspension. The solid samples were prepared by mixing of 2 mL of the suspension with 0.04 mL of the 50 mg/mL solution of Pt catalyst in THF, followed by curing in nitrogen at 60° C. for 3 h and annealing in nitrogen at 100° C. for 12 h. Samples in a form of a 0.25 mm coating on a glass slide and a 2 mm thick flat cast piece were prepared.

Characterization.

FIG. 1 contains the UV-Vis transmission spectrum of the 0.25 mm coating on the glass slide. The transmission in the visible range of the spectra is 94-96%. The mixture before curing was opaque, while the material became more transparent during the curing, due to the change in refractive index resulting from the chemical reaction. FIG. 3 contains the thermogram of the 30-mg piece of the material heated in the thermogravimetric analyzer in air at 400° C. The silica-coated material demonstrates superior thermal stability compared to both the commercial HB-rated silicone and the unfilled material. The purpose of adding silica to the siloxane mixture is to increase viscosity of the resin. Higher viscosity is often required in casting to prevent leaking in the mold. Addition of silica to the mixture of siloxane monomers eliminates the pre-curing step which was utilized in Example 1. As an extra benefit, presence of silica increases thermal stability of the polycyclic polysiloxane material, while only moderately impacting the optical transparency.

### Example 3

### Sample Preparation

In this example, a mixture of 6.1 mL D⁴_{V} and 4.3 mL of D⁴_{H}, and Pt catalyst was prepared as described in Example 1. The mixture was pre-cured at 60° C. for 30 minutes in a closed glass vial to increase the viscosity. To 2 g of the viscous liquid, 70 mg of a yttrium aluminum garnet-based phosphor was added to yield 3.5 wt. % of the phosphor concentration, and the mixture was homogenized in a centrifugal planetary mixer for 2 minutes, followed by pouring into a flat mold and curing in nitrogen at 60° C. for 18 hours and further annealing in nitrogen at 100° C. for 3 hours. As a reference, a typical commercial two-part methyl silicone was mixed with 3.5 wt. % of the same phosphor and cured in the mold according to the recommended procedure. Both the sample and the reference material were shaped into 10 mm disks with a thickness of 2 mm.

Characterization.

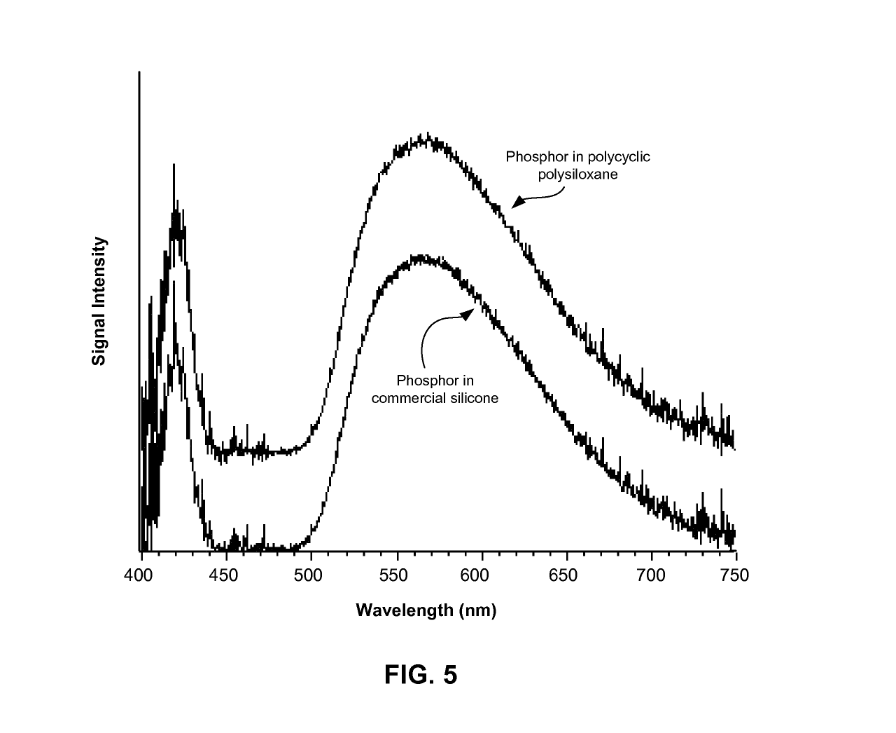

Each sample was placed on top of a blue LED (440 nm) package and inserted into an integrating sphere photometer. A power of 0.09 W was applied to the LED for 1 second and the visible emission (400-750 nm) of the sample was collected. FIG. 5 compares the emission spectra for the polycyclic polysiloxane and reference silicone samples. Aside from a small variation in the calculated color coordinates due to a slight difference in thickness, the emission spectra from both samples was essentially the same. These results indicate that the phosphor exhibits the same optical properties in polycyclic polysiloxane as it does in typical silicones, which implies applicability of these polysiloxanes for phosphor encapsulation in LED devices.

### Example 4

### Sample Preparation

In this example, 1.5 mL (d=0.998 g/cm³) of D⁴_{V} was mixed with 1.075 mL (d=0.991 g/cm³) of D⁴_{H}, and 0.2 mL of the 50 mg/mL solution of platinum divinyltetramethyldisiloxane complex in tetrahydrofuran (THF) was added. In order to measure water vapor permeability, the mixture was poured into a round aluminum dish with diameter of 35 mm, and cured in nitrogen at 60° C. for 3 hours, followed by annealing in nitrogen at 100° C. for 12 hours, producing a 2 mm flat sample.

Water Vapor Permeability Test

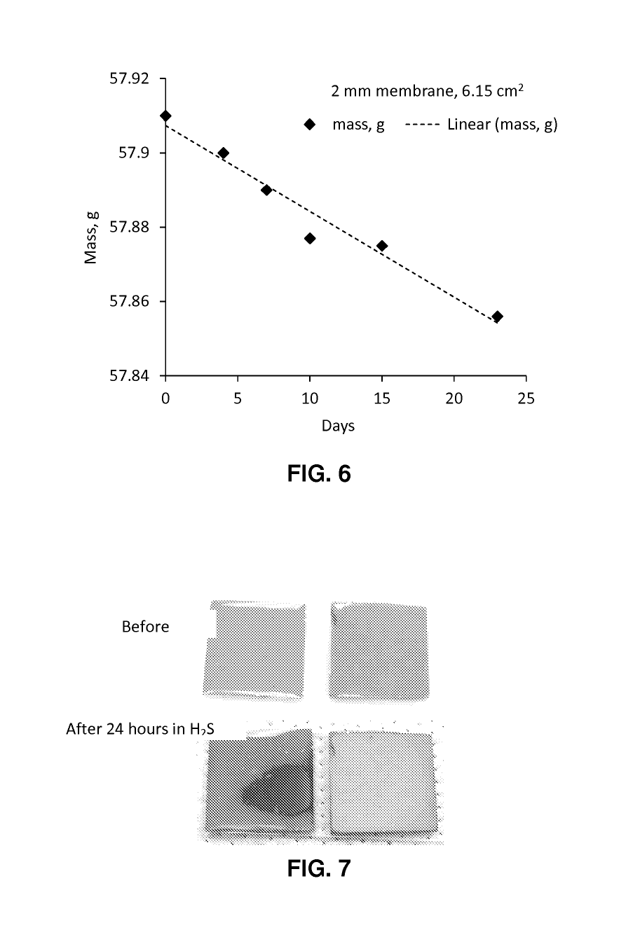

A glass cup with the interior diameter of 28 mm and the wall thickness of 1.5 mm was filled with distilled water to the level of ¼″ below the top, and the prepared sample of crosslinked polycyclic polysiloxane was glued on the top of the cup with epoxy resin. The total weight of the assembly was 57.91 g. The assembly was placed in a dessicator equipped with a nitrogen inlet and outlet. Dry nitrogen was constantly purged through the dessicator at a flow rate of 1 L/min, providing a relative humidity of 0.5%, as measured by a digital hygrometer. The assembly was measured periodically over the course of 23 days. FIG. 6 presents the loss of water through the polymeric membrane as a function of time. The slope of the plot allows calculation of the water vapor permeability of 23 mg/day, which considering the thickness of 2 mm and the area of 6.15 cm² gives the value of 7.5 g·mm/m²/day. This value is 2 times lower than that for phenyl silicones and 7 times lower than that for methyl silicones.

Silver Coating Protection Tests.

The purpose of this test was to compare the rate of penetration of hydrogen sulfide through a layer of the polycyclic polysiloxane polymer with a similar layer of a typical methyl silicone polymer. Hydrogen sulfide is a product of microbial metabolism that is often present in the air. This compound is the primary source of corrosion of silver parts in electronics; therefore high barrier properties of the encapsulating resins are important for reliability of the LED products.

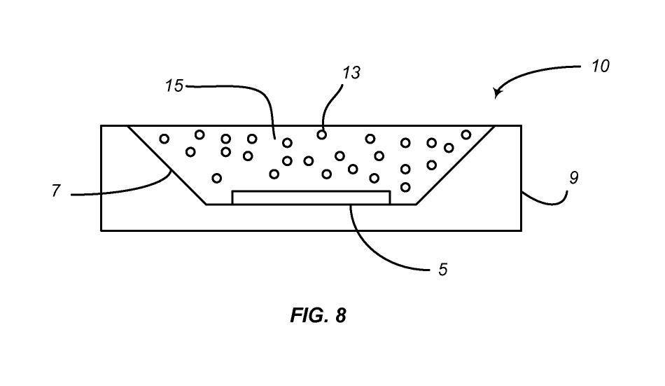

For these tests, two 25×25 mm glass slides were coated with a layer of silver by vacuum sputter coating. On one slide, a layer of a methyl silicone coating was placed. On the other slide a mixture of cyclic siloxanes with the catalyst, as described above was deposited. Both samples were cured in nitrogen at 100° C. for 2 hours, yielding a 0.2 mm thick coating on each slide. The slides were placed in a desiccator. As a source of hydrogen sulfide, 1 g of sodium sulfide was placed into the same desiccator in a small cup and a few drops of 1% hydrochloric acid solution were added to it. The desiccator was closed and was kept at room temperature for 24 hours. The top image in FIG. 7 shows the two slides (silicone-coated on the left, polycyclic polysiloxane-coated on the right) before the test, and the bottom image shows the same slides after 24 hours in the presence of hydrogen sulfide. Significant corrosion of the silver can be observed in the slide coated with methyl silicone, whereas the slide coated with the polycyclic polysiloxane appears unaffected. This experiment indicates that the polycyclic polysiloxane polymer has superior barrier properties compared to methyl silicone.

FIG. 8 is an illustration of a phosphor-conversion LED 10. A blue-emitting LED die 5 is shown here mounted in a module 9 having a well 7 with reflective sides. LED die 5 is encapsulated in a polycyclic polysiloxane polymer 15 according to this invention in which particles of a phosphor 13 are dispersed. The phosphor is preferably a cerium-activated yttrium aluminum garnet phosphor (YAG:Ce). Although in this embodiment phosphor particles are included in the polycyclic polysiloxane polymer, this invention is not constrained to phosphor-conversion LEDs and the polycyclic polysiloxane polymer may be used by itself as an encapsulant in other LED types, including monochromatic LEDs.

While there have been shown and described what are at present considered to be the preferred embodiments of the invention, it will be apparent to those skilled in the art that various changes and modifications can be made herein without departing from the scope of the invention as defined by the appended claims.

What is claimed is:

1. An LED light source, comprising: an LED die and a polymer consisting of a polycyclic polysiloxane polymer, the polycyclic polysiloxane polymer having the general structure: 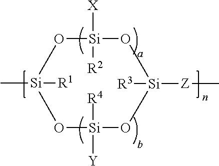
wherein:
(i) Si and O are atoms of silicon and oxygen, respectively, and the structure between the brackets is a repeating unit of the polymer, where n is an integer from 10 to 1000000, and a+b is an integer from 1 to 4;
(ii) R¹, R², R³ and R⁴ are functional groups selected from the group consisting of:
(a) any saturated aliphatic hydrocarbon group of the general formula of CₙH₍₂ₙ₊₁₎, where n is an integer from 1 to 20;
(b) any unsaturated aliphatic hydrocarbon group of the general formula of CₙH₍₂ₙ₋₁₎, where n is an integer from 1 to 20;
(c) any cyclic hydrocarbon group wherein the number of carbon atoms in the cycle is from 4 to 10;
(d) any aromatic hydrocarbon group of the general formula of C₍₆₊ₙ₎H₍₅₊₂ₙ₎ where n is an integer from 0 to 10; and
(e) any fluorocarbon group of the general formula C₂H₄CₙF₍₂ₙ₊₁₎ where n is an integer from 1 to 20;
(iii) Z is selected from the group consisting of:
(a) an oxygen atom;
(b) a siloxane group of the general formula —O—(SiR₂O)ₘ, where R is a functional group of the same type as any one of R¹, R², R³ and R⁴, and m is an integer from 1 to 3; and
(c) a hydrocarbon group of the general formula of (CH₂)ₘ, where m is an integer from 1 to 20;
and, (iv) X and Y are selected from the group consisting of the R¹, R², R³ and R⁴ functional groups and cross-linking sites that connect to cyclosiloxane rings in other polymeric chains to form a 3-dimensional cross-linked structure.

2. The LED light source of claim 1 wherein the polymer encapsulates the LED die.

3. The LED light source of claim 1 wherein the polymer forms an optical element of the LED light source.

4. The LED light source of claim 3 wherein the optical element is a lens.

5. The LED light source of claim 1 wherein the polymer contains particles of a phosphor.

6. The LED light source of claim 5 wherein the phosphor is a YAG:Ce phosphor.

7. An LED light source, comprising: an LED die and a polymer consisting of a polycyclic polysiloxane polymer, the polycyclic polysiloxane polymer having the general structure: 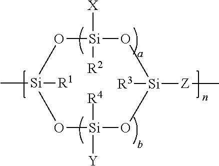
wherein:
(i) Si and O are atoms of silicon and oxygen, respectively, and the structure between the brackets is the repeating unit of the polymer, where n is an integer from 10 to 1000000, and a+b is an integer from 1 to 4;
(ii) R¹, R², R³ and R⁴ are functional groups selected from the group consisting of:
(a) any saturated aliphatic hydrocarbon group of the general formula of CₙH₍₂ₙ₊₁₎, where n is an integer from 1 to 3;
(b) any unsaturated aliphatic hydrocarbon group of the general formula of CₙH₍₂ₙ₋₁₎, where n is an integer from 3 to 5;
(c) any cyclic hydrocarbon group wherein the number of carbon atoms in the cycle is from 4 to 10;
(d) any aromatic hydrocarbon group of the general formula of C₍₆₊ₙ₎H₍₅₊₂ₙ₎ where n is an integer from 0 to 4; and
(e) any fluorocarbon group of the general formula C₂H₄CₙF₍₂ₙ₊₁₎ where n is an integer from 1 to 3;
(iii) Z is selected from the group consisting of:
(a) an oxygen atom;
(b) a siloxane group of the general formula —O—(SiR₂O)ₘ, where R is a functional group of the same type as any one of R¹, R², R³ and R⁴, and m is an integer ranging from 1 to 3; and
(c) a hydrocarbon group of the general formula of (CH₂)ₘ, where m is an integer ranging from 1 to 2;
and, (iv) X and Y are selected from the group consisting of the R¹, R², R³ and R⁴ functional groups and cross-linking sites that connect to cyclosiloxane rings in other polymeric chains to form a 3-dimensional cross-linked structure.

8. The LED light source of claim 7 wherein the functional groups R¹, R², R³ and R⁴ are selected from the group consisting of CH₃, C₃H₅ and C₂H₄CF₃.

9. The LED light source of claim 7 wherein Z is an oxygen atom.

10. The LED light source of claim 1 wherein a silicon oxide filler has been dispersed in the polymer.

11. The LED light source of claim 10 wherein the silicon oxide filler comprises up to 70 percent by weight of the combined weight of the filler and polymer.
